(19) United States
(12) Patent Application Publication
(10) Pub. No.: US 2020/0139844 A1
(43) Pub. Date: May 7, 2020

(54) A BATTERY STATE OF POWER ESTIMATION METHOD AND A BATTERY STATE MONITORING SYSTEM

(71) Applicant: VOLVO TRUCK CORPORATION, Göteborg (SE)

(72) Inventor: Esteban Gelso, Göteborg (SE)

(21) Appl. No.: 16/488,106

(22) PCT Filed: Mar. 6, 2017
(86) PCT No.: PCT/EP2017/055132

§ 371 Date: Aug. 22, 2019

(51) Int. Cl. B60L 58/12; G01R 31/36; G01R 31/3835; G01R 31/389

(52) U.S. Cl. CPC B60L 58/12; G01R 31/389; G01R 31/3835; G01R 31/3648

(57) ABSTRACT

A method for estimation of state of power for a battery for an electric vehicle is provided. The method comprising: measuring a temperature of the battery, and an output voltage from the battery; receiving a state of charge estimation based on a battery model; providing a SOP estimation model for the battery comprising the measured temperature and the measured output voltage. The method is characterized in that the SOP estimation model further comprises a parameter fault estimate for errors of the measured parameters and/or estimated parameters; and in that the method further comprises estimating the SOP based on the SOP estimation model for a battery.

### TECHNICAL FIELD

The invention relates to a method for robust estimation of state of power (SOP) for a battery. The invention further relates to a computer program comprising program code performing the steps of the method, a computer readable medium carrying such a computer program, a control unit for controlling the monitoring the state of a battery, a battery state monitoring system, and an electrical vehicle comprising such a battery state monitoring system. The electrical vehicle may be heavy-duty vehicles, such as trucks, buses and construction equipment, but may also be used in other vehicles such as smaller electrical industrial vehicles, and passenger cars.

### BACKGROUND

Electrochemical storage devices as batteries are important in modern energy infrastructure. Many different types of equipment rely on battery energy storage. In the transportation industry batteries have always been used for service purposes in vehicles with combustion engines, but as the industry develops electrical propulsion systems, the requirements of energy storage in batteries increase. Charging and discharging of batteries for electrical vehicles have to be quick, safe and reliable. Batteries are larger, has to deliver more power and are used in a more demanding way with more frequent and deeper discharges. In advanced systems as electrical vehicles accurate estimation of the state of power (SOP) of a battery is important to be able to determine the maximum charge current and the maximum discharge power.

The state of power (SOP) capability is very important in the energy management of vehicles with electric power trains. The SOP methods need inputs as for example the state of charge (SOC), the battery cell terminal voltage, and the cell temperature, which come from estimates based on sensor measurements with an associated accuracy or uncertainty. A SOP estimation model is presented in the document US 2016/0131714 A1, which is advanced but has a number of problems with correct power and current estimation. There is thus a need for improved methods, systems and devices for estimation of the SOP of a battery.

### SUMMARY

An object of the invention is to improve the current state of the art, to solve the above problems, and to provide an improved method for estimation of state of power for a battery, e.g. for an electric vehicle. These and other objects are according to a first aspect of the invention achieved by a method for estimation of state of power for a battery for an electric vehicle, the method comprising: measuring a temperature of the battery, and an output voltage from the battery; receiving a state of charge estimation based on a battery model; providing a SOP estimation model for the battery comprising the measured temperature and the measured output voltage. The method is characterized in that the SOP estimation model further comprises a parameter fault estimate for errors of the measured parameters and/or estimated parameters; and in that the method further comprises estimating the SOP based on the SOP estimation model for a battery. These parameters could include, for example, the cell capacity, the ohmic resistance, and other resistances and capacitances, which are estimated and have associated an error or uncertainty.

Problems of the prior art are thereby solved in that the presented method will increase the accuracy of the SOP estimation as it will analyze the effects of uncertainties/errors in battery model parameters and measurements in the SOP estimate. Such uncertainties and errors could in prior art solutions result, for example, in an underestimate of the maximum discharging/charging current, and consequently, the violation of limits for voltage, power, etc. The method according to the invention however deals with uncertainties in model parameters and measurement errors to overcome these potential underestimation of current/power. The SOP estimation problem may be formulated as a constraint satisfaction problem, which can be solved for example, through interval-based techniques or based on reachability analysis tools and set invariant theory. The battery could be a battery cell or a number of battery cells arranged in a battery pack.

According to a further aspect of the invention the objects are achieved by a computer program comprising program code means for performing the steps of the method described herein, when the computer program is run on a computer.

According to a further aspect of the invention the objects are achieved by a computer readable medium carrying the aforementioned computer program comprising program code means for performing the method, when the program product is run on a computer.

According to a further aspect of the invention the objects are achieved by a control unit for controlling the monitoring of the state of a battery, the control unit comprising a circuit configured to perform a robust estimation of state of charge for a battery, wherein the control unit is arranged to perform the steps of the herein discussed method.

According to a further aspect of the invention the objects are achieved by a battery state monitoring system for monitoring the state of a battery; comprising a temperature sensor arranged to sense the temperature of said battery; a current sensor arranged to measure the output current from said battery; a voltage sensor arranged to measure the output current from said battery; and a control unit as described above. According to a still further aspect of the invention the objects are achieved by an electrical vehicle comprising such a battery state monitoring system.

Further advantages and advantageous features of the invention are disclosed in the following description and in the dependent claims.

### BRIEF DESCRIPTION OF THE DRAWINGS

With reference to the appended drawings, below follows a more detailed description of embodiments of the invention cited as examples.

In the drawings:

FIG. 1 is a schematic view of a circuit performing the inventive method for estimating the SOP for a battery.

FIG. 2 is a schematic view of a battery state monitoring system for monitoring the state of a battery comprising the circuit of FIG. 1 in a control unit, sensors for measuring battery properties and a circuit providing a state of charge (SOC) of the battery.

FIG. 3 is block diagram showing the inventive method for estimating the SOP for a battery.

FIG. 4 is schematic view of an electrical vehicle comprising the battery state monitoring system of FIG. 3.

FIG. 5 is a schematic view describing an equivalent circuit model of a battery cell.

### DETAILED DESCRIPTION OF EXAMPLE EMBODIMENTS OF THE INVENTION

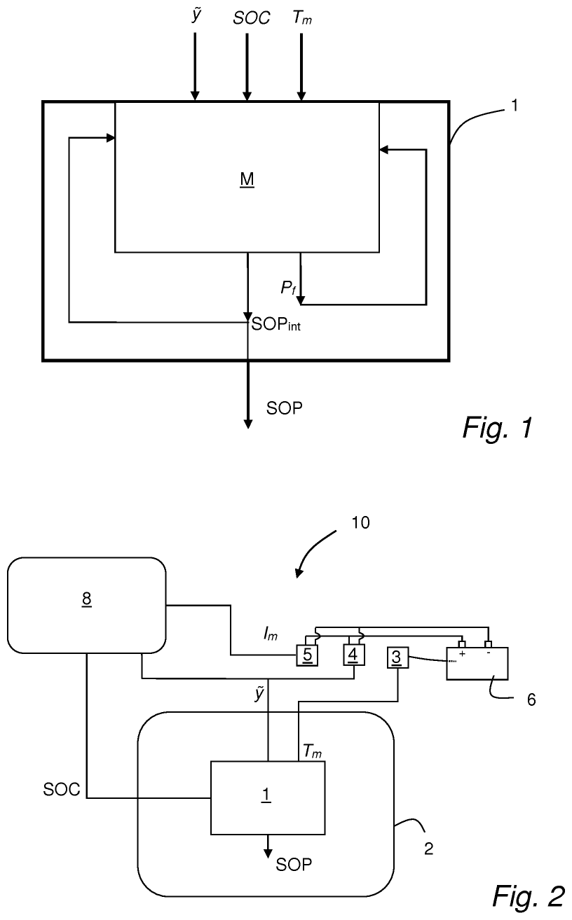

FIG. 1 is a schematic view of a circuit 1 performing the inventive method M for estimating the SOP for a battery from measured values of the temperature Tₘ, estimated SOC and output voltage \tilde{y} of the battery. An intermediate SOP value (SOPᵢₙₜ), and parameter fault estimate (P_{f}) for errors of the measured parameters and/or estimated parameters are iterated in the model to optimize the value of an estimated SOP value (SOP).

FIG. 2 is a schematic view of a battery state monitoring system 10 for monitoring the state of a battery 6 comprising a control unit containing the circuit 1 of FIG. 1. A voltage sensor 5 measures the output voltage of the battery 6, a current sensor 4 measures the current of the battery 6 and a temperature sensor 3 measures the temperature of the battery 6 cell. A state of charge estimation unit 8 is available to provide the input SOC required by the model according to the present invention.

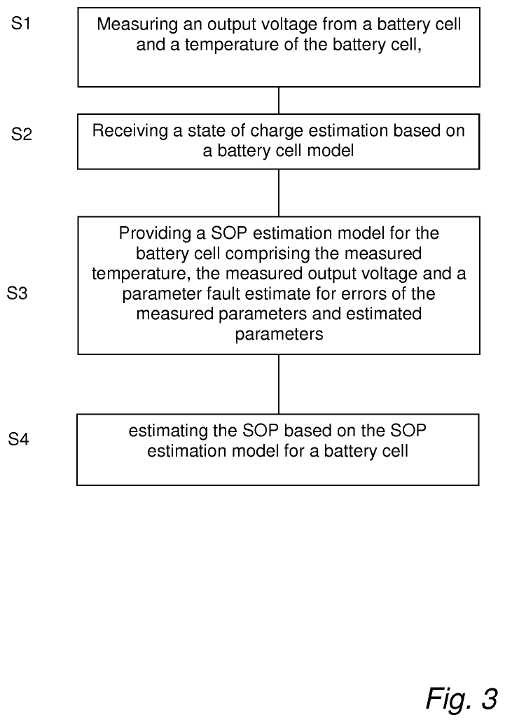

With reference to FIG. 3 the main steps of the inventive method for estimating the SOP for a battery will be explained. In a first step S1 the method is measuring a temperature of the battery, and an output voltage from the battery. In a second step S2 an estimation of the battery SOC is provided. In a third step S3 the method it is provided a SOP estimation model for the battery comprising the measured temperature, the measured output voltage and a parameter fault estimate for errors of the measured parameters and estimated parameters. In a fourth step S4 the method is estimating the SOP based on the SOP estimation model for a battery.

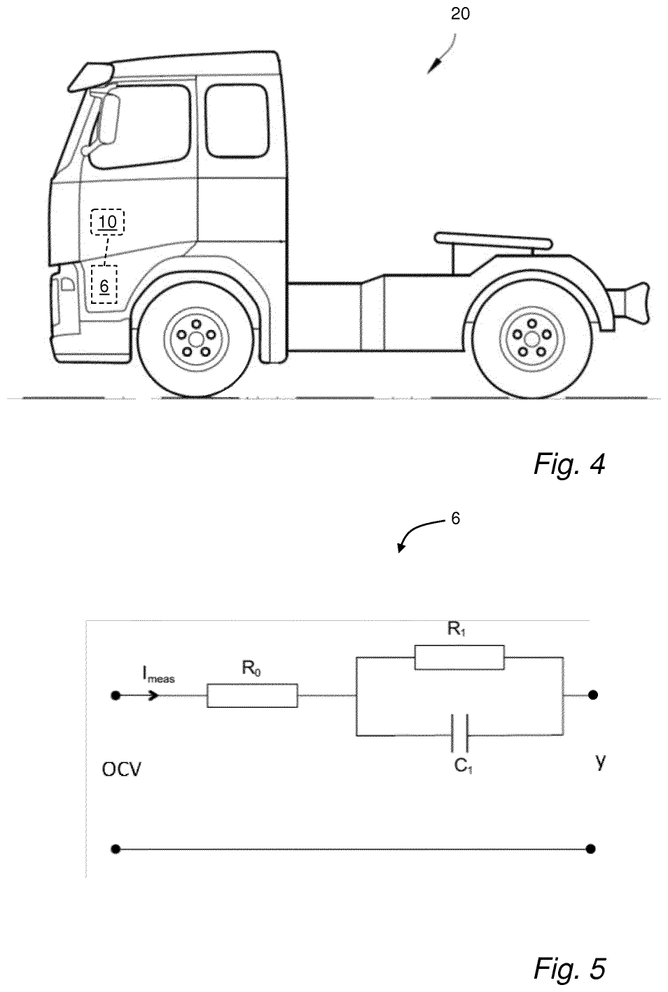

FIG. 4 is schematic view of an electrical vehicle 20 comprising the battery state monitoring system 10 shown in FIG. 3 connected to a battery 6 of the electrical vehicle.

The inventive method will now be discussed more in detail with exemplifying mathematic expressions for carrying out the method.

Uncertainties in the battery model parameters and measurement errors are taken into account in the SOP estimation.

An equivalent circuit model of a battery can be composed of passive elements such as resistors and capacitors which schematically are connected between two terminals representing an open circuit voltage OCV of a battery, and two terminals representing an estimated voltage value ‘y’ of a battery. The resistance Rₒ in FIG. 5 corresponds to the ohmic resistance, whereas the parallel-coupled resistance R, and capacitor C, can be seen to represent the dynamic characteristics of a battery. Note that the model can be extended with more parallel-coupled RC branches to represent more complex dynamics. The expressions for the mathematical representation of the battery model like

$${x}_{1} ( k + 1 ) = {x}_{1} ( k ) ( 1 - \frac{1}{{C}_{1} {R}_{1}} ) - \frac{1}{{C}_{1}} ( i ( k ) ) + {w}_{1 ( k )}$$

$${x}_{2} ( k + 1 ) = {x}_{2} ( k ) - \frac{η \cdot {T}_{s}}{{C}_{n}} ( i ( k ) ) + {w}_{2} ( k )$$

the one shown in FIG. 5 are as follows:
where x₁ is the voltage of the parallel-coupled RC branch, x₂ is the SOC, η is the Coulombic efficiency of the battery, Ts is the sampling time, Cn is the battery capacity, and w=[w1 w2]^{T} is the process noise.

In a more compact expression, it can be written as:

x(k+1)=A·x(k)+B·i(k)+w(k),

where x(k)=[x₁(k)x₂(k)]^{T}

The output voltage is defined as:

y=(k)=OCV(x₂(k))−R₀(i(k)+v(k),

where the open circuit voltage OCV is in this case a function of the variable x2, i.e. the SOC; and v is the observation noise.

The expression can also be written in a more compact way as:

y(k)=g(x(k), i(k)+v(k)

Note that the following parameters of the model: C₁, R₁, R₀, η, and Cₙ can be time variant in the previous model, that is they can change the value with time depending on e.g. cell current, temperature and SOC. Additional states can also be included to consider the cell temperature prediction.

The SOP estimation problem is formulated as a constraint satisfaction problem, which can be solved for example, through interval-based techniques or based on reachability analysis tools and set invariant theory

Denote by,

(1) V={z1, . . , zn}, a set of n numeric variables
(2) D={Z1, . . . ,Zn}, a set of domains where Zi, a set of numeric values, is the domain associated with the variable zi,
(3) C(z)={(C1(z), . . . , Cm(z)}, a set of m constraints where a constraint Ci(z) is determined by a numeric relation (equation, inequality, inclusion, etc.) linking a set of variables under consideration.

We let CSP=(V,D, C(z)), denote a CSP and introduce the following definition, Definition 1. The solution of a CSP, solution (CSP=(V,D, C(z))) is the set of numerical variables Σ for which all the constraints Ci∈C can be satisfied i.e.,

Σ={z∈Z|Ci(z) holds ∀Ci∈C}

For example, assuming estimates of the state vector at time step k available, i.e. x₁(k) and x₂(k), the SOP estimation CSP over a 1-step horizon with uncertainties in R₀, and Cₙ can now be stated as,

V={x(k), x(k+1), eₓ,(k), e_{y}(k), i(k), i(k+1), R₀, Cₙ}

D={xₖ, xₖ₊₁, ε_{x,k}ε_{y,k}, [symbol] (k), [symbol] (k+1), [symbol] ₀, [symbol] ₙ}

C={yₖ₊₁^{MIN}≤g(x(k+1),i(k+1),R₀)≤yₖ₊₁^{MAX}

x(k+1)=A·x(k)+B(Cₙ)·i(k)

yₖ^{MIN}≤y(k)=g(x(k),i(k),R₀≤yₖ^{MAX}

\tilde{x}(k)=x(k)+eₓ(k)

\tilde{y}(k)=y(k)+e_{y}(k)}.

Where \tilde{x}(k) and \tilde{y}(k) are the estimate vectors of the state variables (SOC and RC voltage in the previous example) and the battery terminal voltage, and eₓ(k) and e_{y}(k) represent the uncertainty associated with the estimates.

The uncertainty is considered unknown but bounded, i.e. for example e(k) ⊖∈ₖ.

I(k) and I(k+1) are the domains of the future cell current, for which the initial domains could be simply obtained from specifications of maximum and minimum currents, or they could come from a desire domains.

The prediction horizon of N steps can be formulated by repetition of the previous CSP.

From this method, the trajectory or envelopes of signals like SOC, battery voltage and current (so that power) could be obtained, when considering the limits on e.g. SOC, voltage, and current.

If the obtained solution 1 of the CSP is empty a no-solution flag is set, sending this information to other functionalities, like an energy management system, to indicate that any current (or power) profile belonging to the initial domains specified cannot be handled by the battery to act accordingly.

It is to be understood that the present invention is not limited to the embodiments described above and illustrated in the drawings; rather, the skilled person will recognize that many changes and modifications may be made within the scope of the appended claims.

1. A method for estimation of state of power (SOP) for a battery (6) (for an electric vehicle), the method comprising:
measuring a temperature (Tₘ) of the battery, and an output voltage (\tilde{y}) from the battery;
receiving a state of charge (SOC) estimation based on a battery model;
providing a SOP estimation model (M) for the battery comprising the measured temperature (Tₘ) and the measured output voltage (\tilde{y});
characterized in that
the SOP estimation model (M) further comprises a parameter fault estimate (P_{ƒ}) for errors of the measured parameters and/or estimated parameters; and
in that the method further comprises estimating the SOP based on the SOP estimation model (M) for a battery.

2. The method according to claim 1, wherein the state of charge (SOC) estimation is based on a battery model comprising cell capacity, ohmic resistance and cell capacitance.

3. The method according to claim 1, wherein the error of the measured voltage (\tilde{y}ₘ) is based on errors such as bias or drift in the voltage sensor (5).

4. The method according to claim 1, wherein the SOP estimation model (M) is formulated as a constraint satisfactory problem (CSP) and solved based on interval-based techniques, or based on reachability analysis and set invariant theory.

5. The method according to claim 4, wherein the SOP estimation model (M) is based on
a battery cell described by
$${x}_{1} ( k + 1 ) = {x}_{1} ( k ) ( 1 - \frac{1}{{C}_{1} {R}_{1}} ) - \frac{1}{{C}_{1}} ( i ( k ) ) + {w}_{1 ( k )}$$
$${x}_{2} ( k + 1 ) = {x}_{2} ( k ) - \frac{η \cdot {T}_{s}}{{C}_{n}} ( i ( k ) ) + {w}_{2} ( k )$$
the output voltage is defined by
y(k)=OCV(x₂(k))−R₀(i(k))+x₁(k)+v(k);
and
CSP is denoted by: CSP=(V,D, C(z)), where
(1) V={z1, . . . , zn}, a set of numeric variables,
(2) D={Z1, . . . , Zn}, a set of domains where Zi, a set of numeric values, is the domain associated with the variable zi,
(3) C(z)={C1(z), . . , Cm(z)}, a set of constraints where a constraint Ci(z) is determined by a numeric relation (equation, inequality, inclusion, etc.) linking a set of variables under consideration;
where the solution of a CSP, solution(CSP−(V,D, C(z))) is the set of numerical variables Σ for which all the constraints Ci∈C can be satisfied.

6. The method of claim 5, wherein Σ={z ∈Z|Ci(z) holds ∀Ci ∈C} assuming estimates of the state vector at time step k available, i.e. x₁(k) and x₂(k),
wherein the SOP estimation CSP over a 1-step horizon with uncertainties in R₀, and Cₙcan be stated as,
V={x(k), x(k+1), eₓ(k), e_{y}(k), i(k), i(k+1), R₀, Cₙ}
D={Xₖ, Xₖ₊₁, ε_{x,k}, ε_{y,k}, [symbol] (k), [symbol] (k+1), [symbol] ₀, [symbol] ₙ}
C={yₖ₊₁^{MIN}≤g(x(k+1), i(k+1), R₀)≤yₖ₊₁^{MAX}
x(k+1)=A·x(k)+B(Cₙ)·i(k)
yₖ^{MIN}≤y(k)=g(x(k),i(k), R₀)≤yₖ^{MAX}
\tilde{x}(k)=x(k)+eₓ(k)
\tilde{y}(k)=y(k)+e_{y}(k)}.
where \tilde{x} and \tilde{y} are the estimate vectors of the state variables (SOC and RC voltage in the previous example) and the battery terminal voltage, and eₓ(k) and e_{y}(k) represent the uncertainty associated with the estimates; and
where the uncertainty is considered unknown but bounded and I(k) and I(k+1) are the domains of the future cell current.

7. The method according to claim 5, wherein the parameters of the model: C₁, R₁, R₀, η, and Cₙ are time variant, that is they can change the value with time depending on e.g. cell current, temperature and SOC.

8. The method according to claim 5, wherein additional states are also included to consider the cell temperature prediction.

9. A computer program comprising program code means for performing the steps of claim 1, when said program is run on a computer.

10. A computer readable medium carrying a computer program comprising program code means for performing the steps of claim 1, when said program product is run on a computer.

11. A control unit (2) for controlling the monitoring the state of a battery (6), the control unit comprising a circuit (1) configured to perform an estimation of state of power (SOP) for a battery (6), wherein the control unit (2) is arranged to perform the steps of the method according to claim 1.

12. A battery state monitoring system for monitoring the state of a battery (6); comprising a temperature sensor (3) arranged to sense the temperature of said battery (6);
a voltage sensor (5) arranged to measure the output current (\tilde{y}ₘ) from said battery (6); and a control unit (2) according to claim 11.

13. An electrical vehicle comprising the battery state monitoring system according to claim 12.
